(19) United States
(12) Patent Application Publication
(10) Pub. No.: US 2018/0052787 A1
(43) Pub. Date: Feb. 22, 2018

(54) MEMORY SYSTEM SUPPORTING AN OFFSET COMMAND

(71) Applicant: Samsung Electronics Co., Ltd., Suwon-si (KR)

(72) Inventors: Jong-pil Son, Seongnam-si (KR); Seong-il O, Suwon-si (KR)

(21) Appl. No.: 15/681,917

(22) Filed: Aug. 21, 2017

(30) Foreign Application Priority Data
Aug. 22, 2016 (KR) 10-2016-0106175

(51) Int. Cl. G06F 13/16; G11C 7/22

(52) U.S. Cl. CPC G06F 13/1689; G06F 12/0676; G11C 7/222

(57) ABSTRACT

A memory system that supports an offset command includes a memory controller and a memory device. The memory controller may issue an offset command to the memory device for one cycle of a clock signal, the offset command does not include an access address signal, but includes an offset signal from which the access address signal can be derived. The memory device may receive the offset command and may generate an access address signal based on the offset signal of the offset command.

### CROSS-REFERENCE TO RELATED APPLICATION

This application claims the benefit of Korean Patent Application No. 10-2016-0106175, filed on Aug. 22, 2016, in the Korean Intellectual Property Office, the disclosure of which is incorporated herein in its entirety by reference.

### FIELD

The inventive concept relates to a memory system, and more particularly, to a memory controller that provides an offset command implying an access address, and a memory device that generates the access address in response to the offset command.

### BACKGROUND

In a dynamic random access memory (DRAM), after an active operation and precharge operation are performed with respect to a row address, the active operation may be performed again with respect to the same row address. The active operation with respect to a row address may be performed in response to an active command issued by a memory controller. The active command may need two clock cycles according to a DRAM standard specification. When more than one active operation with the same row address is expected to be performed, the performance of a memory system including the DRAM may be improved if the active command uses only one clock cycle.

### SUMMARY

Embodiments of the inventive concept provide a memory controller that transmits an offset command from which an access address can be derived.

Embodiments of the inventive concept provide a memory device that generates the access address in response to the offset command.

According to an aspect of the inventive concept, there is provided a memory device comprising a clock receiver configured to receive an external clock signal from a controller, and a control circuit configured to receive an offset command signal from the controller in synchronization with the clock signal, the offset command signal not comprising an access address signal, and to generate an access address signal based on an the offset command signal.

According to another aspect of the inventive concept, there is provided a memory controller comprising a clock transmitter configured to transmit a clock signal to controller memory device; and a command generator configured to transmit the offset command signal in synchronization with the clock signal, but comprising an offset signal that comprises access address offset information.

According to another aspect of the inventive concept, a memory device comprises a clock receiver configured to receive a clock signal from a memory controller and a control circuit that is configured to receive a first command signal comprising first access address signals in synchronization with n cycles of the clock signal and is configured to receive a second offset command signal comprising an offset signal based on the first access address signals in synchronization with m cycles of the clock signal. The control circuit is further configured to generate second access address signals based on the offset signal; and m is less than n.

It is noted that aspects of the inventive concepts described with respect to one embodiment, may be incorporated in a different embodiment although not specifically described relative thereto. That is, all embodiments and/or features of any embodiment can be combined in any way and/or combination. These and other aspects of the inventive concepts are described in detail in the specification set forth below.

### BRIEF DESCRIPTION OF THE DRAWINGS

Example embodiments of the inventive concept will be more clearly understood from the following detailed description taken in conjunction with the accompanying drawings in which:

FIG. 1 is a block diagram illustrating a memory system that supports an offset command according to example embodiments of the inventive concept;

FIG. 2 is a block diagram illustrating a memory controller that issues the offset command in FIG. 1 according to example embodiments of the inventive concept;

FIG. 3 is a table illustrating an active command provided by a command generator of FIG. 2 according to example embodiments of the inventive concept;

FIG. 4 includes tables illustrating an active offset command provided by the command generator of FIG. 2 according to example embodiments of the inventive concept;

FIG. 5 is a timing diagram of the active command of FIG. 3 and the active offset command of FIG. 4 according to example embodiments of the inventive concept;

FIG. 6 is a table illustrating a read commend provided by the command generator of FIG. 2 according to example embodiments of the inventive concept;

FIG. 7 is a table illustrating a write command provided by the command generator of FIG. 2 according to example embodiments of the inventive concept;

FIG. 8 includes tables illustrating a read or write offset command provided by the command generator of FIG. 2 according to example embodiments of the inventive concept;

FIG. 9 is a timing diagram of the read command of FIG. 6 and the read offset command of FIG. 8, and a timing diagram of the write command of FIG. 7 and the write offset command of FIG. 8 according to example embodiments of the inventive concept;

FIG. 10 is a block diagram of the memory device of FIG. 1 according to example embodiments of the inventive concept;

FIG. 11 is a diagram illustrating an access row address generated according to an active offset command in a memory device of FIG. 10 according to example embodiments of the inventive concept;

FIG. 12 is a diagram illustrating an access column address generated according to a read or write offset command in the memory device of FIG. 10 according to example embodiments of the inventive concept; and

FIG. 13 is a block diagram illustrating an example of a computer system that includes a memory system supporting an offset command according to example embodiments of the inventive concept.

### DETAILED DESCRIPTION OF THE EMBODIMENTS

The inventive concept will now be described more fully with reference to the accompanying drawings, in which exemplary embodiments are shown. The inventive concept may, however, be embodied in many different forms without departing from the scope of the inventive concept or essential features. These embodiments are only for illustrative purposes and should not be construed as being limited to the embodiments set forth herein.

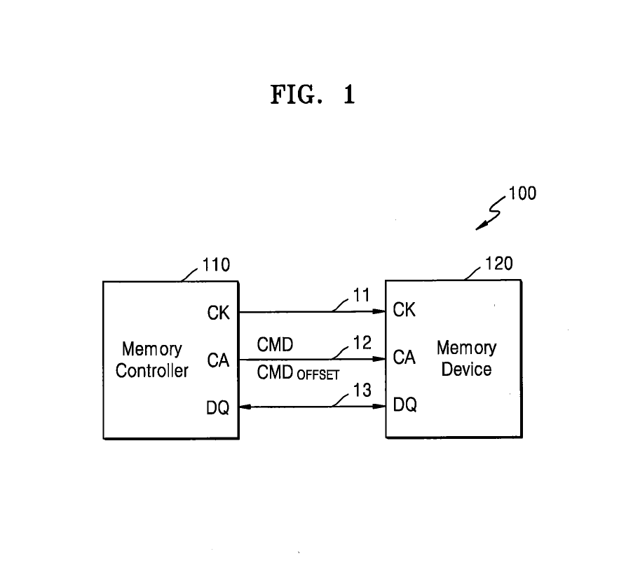

FIG. 1 is a block diagram illustrating a memory system 100 that supports an offset command, according to example embodiments of the inventive concept.

Referring to FIG. 1, the memory system 100 may include a memory controller 110 and a memory device 120. A clock signal line 11, a command/address bus 12, and a DQ bus 13 are connected between the memory controller 110 and the memory device 120.

A clock signal CK generated in the memory controller 110 is provided to the memory device 120 through the clock signal line 11. For example, the clock signal CK may be a continuously alternating inverted signal and may be provided together with an inverted clock signal CKB. This clock signal pair CK and CKB may improve timing accuracy because rising/falling edges thereof are detected at intersections of the signals CK and CKB.

For example, a signal clock signal CK may be provided to the clock signal line 11 as a continuously alternating inverted signal. In this case, to identify a rising/falling edge of the clock signal CK, the clock signal CK may be compared with a reference voltage Vref. However, if a noise fluctuation occurs in the reference voltage Vref, a shift in a detection time of the clock signal CK may occur, which may reduce the timing accuracy compared to the case when using the clock signal pair CK and CKB.

Accordingly, the clock signal line 11 may transfer complementary continuously alternating inverted signals, e.g., the clock signal pair CK and CKB. In this case, the clock signal line 11 may include two signal lines for transferring the clock signal CK and the inverted clock signal CKB. The clock signal CK described in any of the embodiments of the inventive concept may refer to a clock signal pair CK and CKB. For ease of description, the clock signal pair CK and CKB may also be referred to as a clock signal CK.

A command/address signal CA from the memory controller 110 may be provided to the memory device 120 through a command/address bus 12. A command signal or address signal of the memory device 120 may be loaded into the command/address bus 12.

The memory controller 110 may issue a command CMD, including an active command, a read command, a write command, and the like, to the memory device 120 through the command/address bus 12. The command CMD may include a command identification signal indicating whether a corresponding command is an active command, a read command, or a write command, and a bank address signal, a row address signal and a column address signal that indicate an access address of the corresponding command. These signals are transmitted to the memory device 120 through the command/address bus 12.

When the command/address bus 12 is composed of n-bit (where n is a natural number) command/address signals CA, command/address signals CA may be input at both rising/falling edges of the clock signal CK. A command/address signal input at a rising edge of the clock signal CK and a command/address signal input at a falling edge of the clock signal CK may be distinguished from each other as different signals. In this case, 2 n-bit command/address signals CA may be provided to the memory device 120 through an n-bit command/address bus 12.

For example, the command/address bus 12 may be composed of 6-bit command/address signals CA0-CA5. Row address signals may include R0-R15 row addresses, and column address signals may include C2-C9 column addresses. To transfer the command identification signal and row and column address signals included in the command CMD, when the 6-bit command/address signals CA0-CA5 are used, the command CMD may use at least two clock cycles of the clock signal CK.

An address of a current command CMD may be the same as an address of the previous command CMD. In some embodiments, a difference of +1, +2, +3, or the like may appear between the address of the current command CMD and the address of the previous command CMD. Whether a difference of 0, +1, +2, +3, or the like will appear between a current address and a previous address may be known before the memory controller 110 issues the current command CMD to the memory device 120. The difference value between the current address and the previous address will be referred to as an offset value. It is assumed that the memory controller 110 issues an active command as the current command CMD.

In this case, the memory controller 110 may issue an offset command CMD_{OFFSET} to which a command identification signal indicating an active command, and an offset value are assigned. The memory controller 110 may imply an access address to be accessed based on a predetermined bit associated with an offset value of the offset command CMD_{OFFSET}, instead of using multiple bits of address signals that an active command may access. Consequentially, the memory controller 110 may issue an offset command for one clock cycle less than 2 clock cycles of the clock signal.

In some embodiments, the memory controller 110 may issue an offset command CMD_{OFFSET} for one or more clock cycles of the clock signal CK.

The memory controller 110 may issue an offset command CMD_{OFFSET}, including an active offset command, a read offset command, a write offset command, and the like, to the memory device 120 through the command/address bus 12.

The memory device 120 may receive the clock signal CK transmitted through the clock signal line 11 from the memory controller 110, and the command CMD or offset command CMD_{OFFSET} transmitted through the command/address bus 12.

The memory device 120 may receive a command CMD along with the command/address signals CA for 2 clock cycles of the clock signal CK, and receive an offset command CMD_{OFFSET} that does not include an access address signal along with the command/address signals CA for one clock cycle of the clock signal CK.

In some example embodiments, the memory device 120 may receive the offset command CMD_{OFFSET} for one clock cycle or more of the clock signal CK. The memory device 120 may receive the offset command CMD_{OFFSET} through a separate command signal line, not the command/address bus 12 shared by the command/address signals CA.

The memory device 120 may generate an access address signal implied in the offset command CMD_{OFFSET} based on an offset signal assigned to a portion of the command/address signals CA of the offset command CMD_{OFFSET}. The memory device 120 may generate a row address of the access address signal according to an active offset command. The memory device 120 may generate a column address of the access address signal according to a read or write offset command.

The DQ bus 13 may transmit and receive a data signal DQ between the memory controller 110 and the memory device 120. The DQ bus 13 may transmit write data provided from the memory controller 110 to the memory device 120 in response to a write command CMD or write offset command CMD_{OFFSET} issued by the memory controller 110. The DQ bus 13 may transmit read data from the memory device 120 to the memory controller 110 in response to a read command CMD or read offset command CMD_{OFFSET} issued by the memory controller 110.

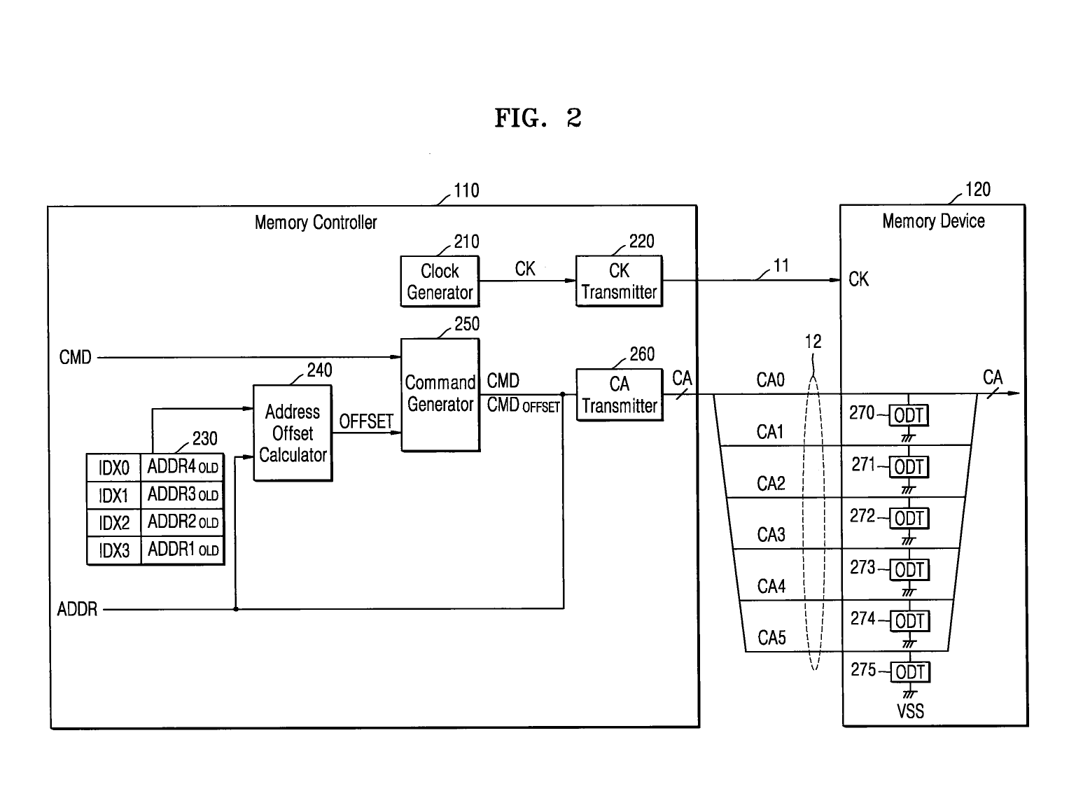

FIG. 2 is a block diagram of the memory controller 110 of FIG. 1 that issues an offset command according to example embodiments of the inventive concept.

Referring to FIG. 2, the memory controller 110 may include a clock generator 210, a clock transmitter 220, a first address storage 230, an address offset calculator 240, a command generator 250, and a command/address (CA) transmitter 260.

The clock generator 210 may generate a clock signal CK. The clock transmitter 220 may transmit the clock signal CK generated by the clock generator 210 to a clock signal line 11. The clock signal CK may be provided to the memory device 120 through the clock signal line 11.

The first address storage 230 may sequentially store addresses provided together with previous commands issued to the memory device 120 by the memory controller 110. The addresses stored in the first address storage 230 may be row addresses or column addresses.

An address provided together with a previous command by the memory controller 110 will be referred to herein as old address. For ease of explanation, it is assumed that a first old address ADDR1_{OLD}, a second old address ADDR2_{OLD}, a third old address ADDR3_{OLD}, and a fourth old address ADDR4_{OLD} are stored in the first address storage 230, wherein the first old address ADDR1_{OLD} is an address provided together with the oldest command issued at the earliest time, and the fourth old address ADDR4_{OLD} is an address provided together with the most recently issued command.

The first address storage 230 may store first to fourth old addresses ADDR1_{OLD}-ADDR4_{OLD} differentiated from one another by index values IDX0-IDX3. For example, a first index value IDX0 may be assigned to the fourth old address ADDR4_{OLD}, a second index value IDX1 may be assigned to the third old address ADDR3_{OLD}, a third index value IDX2 may be assigned to the second old address ADDR2_{OLD}, and a fourth index value IDX3 may be assigned to the first old address ADDR1_{OLD}.

The index values IDX0-IDX3 of the first address storage 230 may be provided as an index of a base address of an offset signal OFFSET calculated by the address offset calculator 240.

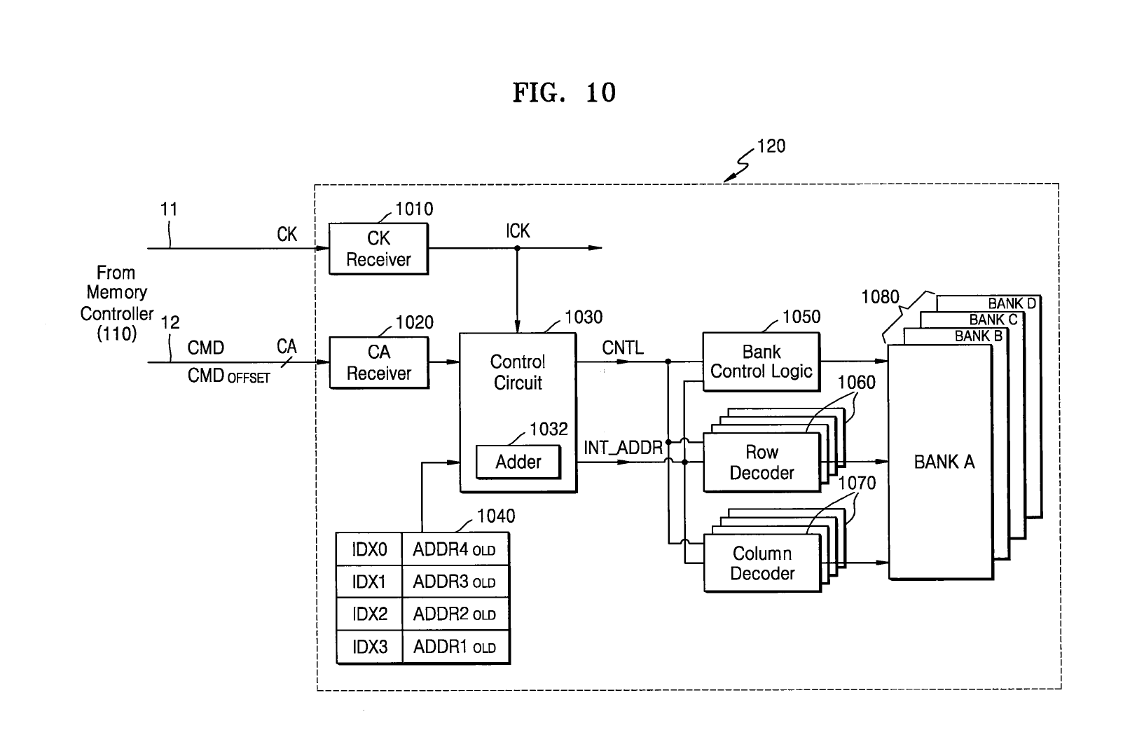

In some embodiments, the old addresses stored in the first address storage 230 may be the same as old addresses stored in a first address storage 1040 of the memory device 120 that will be described later with reference to FIG. 10. That is, the first address storage 230 and the first address storage 1040 may be embodied as the same component/element.

The address offset calculator 240 receives an address ADDR that is to be provided together with a currently issued command CMD from the memory controller 110 (see FIG. 1) to the memory device 120. The address offset calculator 240 compares the current address ADDR of the command CMD with the old addresses stored in the first address storage 230 and outputs an offset signal OFFSET as a result of the comparison.

The address offset calculator 240 may calculate a difference between the current address ADDR and an old address of the first address storage 230 by using, for example, a subtractor. The address offset calculator 240 may output a result of subtraction of a bit value of an old address selected among the old addresses of the first address storage from a bit value of the current address ADDR. The address offset calculator 240 may calculate the result of the subtraction as an offset value.

For example, the address offset calculator 240 may select the fourth old address ADDR4_{OLD} with the first index value IDX0, the address of the most recently issued command, among the old addresses of the first address storage 230. The address offset calculator 240 may calculate an offset value between the current address ADDR and the fourth old address ADDR4_{OLD} as one of 0, +1, +2, and +3. In this case, the address offset calculator 240 may represent these four offset values as 2-bit data values.

In some embodiments, the address offset calculator 240 may set a plurality of offset values, in addition to the four offset values, and represent the offset values as multi-bit data values.

The address offset calculator 240 may set a 2-bit value as 2′b00 when the offset value is 0, as 2′b01 when the offset value is +1, as 2′b10 when the offset value is +2, and as 2′b11 when the offset value is +3. The address offset calculator 240 may output a 2-bit value representing the offset value as an offset signal OFFSET.

The command generator 250 may receive the current command CMD issued by the memory controller 110 and provide the received command CMD to the memory device 120 through the command/address transmitter 260 and a command/address bus 12. The address ADDR provided together with the current command CMD may be provided to the memory device 120 through the command/address transmitter 260 and the command/address bus 12.

The command generator 250 may receive the current command CMD issued by the memory controller 110 and the offset signal OFFSET provided by the address offset calculator 240, generate an offset command CMD_{OFFSET} associated with the offset signal OFFSET, and provide the generated offset command CMD_{OFFSET} to the memory device 120 through the command/address bus 12. The offset command CMD_{OFFSET} does not provide an access address signal of the current command CMD and implies an access address that the current command CMD will access.

The command CMD and the offset command CMD_{OFFSET} provided from the command generator 250 may be set with command/address signals CA[0:5] that are transmitted through the command/address bus 12. The command CMD may include an active command, a read command, and a write command, and each of these commands uses 2 clock cycles of the clock signal CK. The offset command CMD_{OFFSET} may include an active offset command, a read offset command, and a write offset command, and each of these commands uses one clock cycle of the clock signal CK.

The command CMD and the offset command CMD_{OFFSET} may be transmitted to the command/address bus 12 through the command/address transmitter 260. Command/address signals CA[0:5] of the command CMD and the offset command CMD_{OFFSET} may be provided to the memory device 120 through the command/address bus 12.

To receive the command/address signals CA[0:5], the memory device 120 turns on on-die terminators 270-275 connected to command/address signal (CA[0:5]) lines, respectively. The on-die terminators 270-275 may be connected between the command/address signal (CA[0:5]) lines and the power voltage VDD or between the command/address signal (CA[0:5]) lines and the ground voltage VSS. In an example embodiment described with reference to FIG. 2, the on-die terminators 270-275 are connected between the command/address signal (CA[0:5]) lines and the ground voltage VSS).

When the memory device 120 receives the command CMD, the on-die terminators 270-275 may be turned on for 2 clock cycles of the clock signal CK. On the other hand, when the memory device 120 receives the offset command CMD_{OFFSET}, the on-die terminators 270-275 may be turned on for one clock cycle of the clock signal CK.

The turn-on time of the on-die terminators 270-275 may be reduced when the memory device 120 receives the offset command CMD_{OFFSET} compared to when the memory device 120 receives the command CMD. Accordingly, the memory device 120 may reduce the current consumption of the on-die terminators 270-275 and the power consumption when the offset command CMD_{OFFSET} is received.

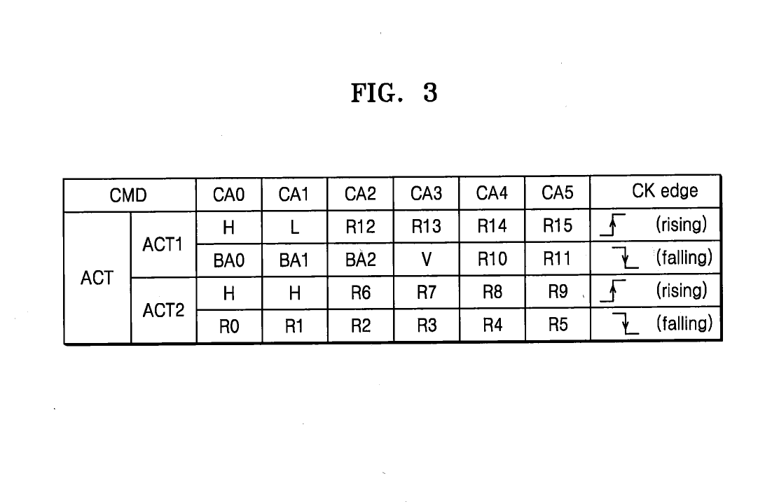

Hereinafter, types, setting, and timing of the command CMD and the offset command CMD_{OFFSET} issued in the memory controller 110 of FIG. 2 will be described in greater detail with reference to FIGS. 3 to 9.

FIG. 3 is a table illustrating an active command ACT provided by the command generator 250 of FIG. 2 according to example embodiments of the inventive concept.

Referring to FIG. 3, the active command ACT may be set with the command/address signals CA[0:5], and may include a first active command ACT1 and a second active command ACT2 that use 2 clock cycles of the clock signal CK.

The first active command ACT1 may set a command identification signal indicating the first active command itself, address signals R10-R15 indicating some of the row addresses R0-R15, and bank address signals BA0-BA2 indicating bank addresses along with the command/address signals CA[0:5].

The first active command ACT1 may represent the first active command ACT1 itself by setting command/address signals CA0 and CA1 to logic high (H) and logic low (L), respectively, at a rising edge of the first clock cycle of the clock signal CK, and may set the command/address signals CA2, CA3, CA4, and CA5 as row address signals R12, R13, R14, and R15, respectively, at a rising edge of the first clock cycle of the clock signal CK.

At a falling edge of the first clock cycle of the clock signal CK, the first active command ACT1 may set the command/address signals CA0, CA1, and CA2 as bank address signals BA0, BA1, and BA2, respectively, and the command/address signals CA4 and CA5 as row address signals R10 and R11 row address signal, respectively, and may not use the command/address signal CA3 (as denoted by V).

The second active command ACT2 may set a command identification signal indicating the second active command itself and the address signals R0-R9 indicating the rest of the row addresses R0-R15 with the command/address signals CA[0:5].

The second active command ACT2 may represent the second active command ACT2 itself by setting both the command/address signals CA0 and CA1 to logic high (H) at a rising edge of the second clock cycle of the clock signal CK, and may set the command/address signals CA2, CA3, CA4, and CA5 as row address signals R6, R7, R8, and R9, respectively, at a rising edge of the first clock cycle of the clock signal CK.

At a falling edge of the second clock cycle of the clock signal CK, the second active command ACT2 may set the command/address signals CAO, CA1, CA2, CA3, CA4, and CA5 as row address signals RO, R1, R2, R3, R4, and R5, respectively.

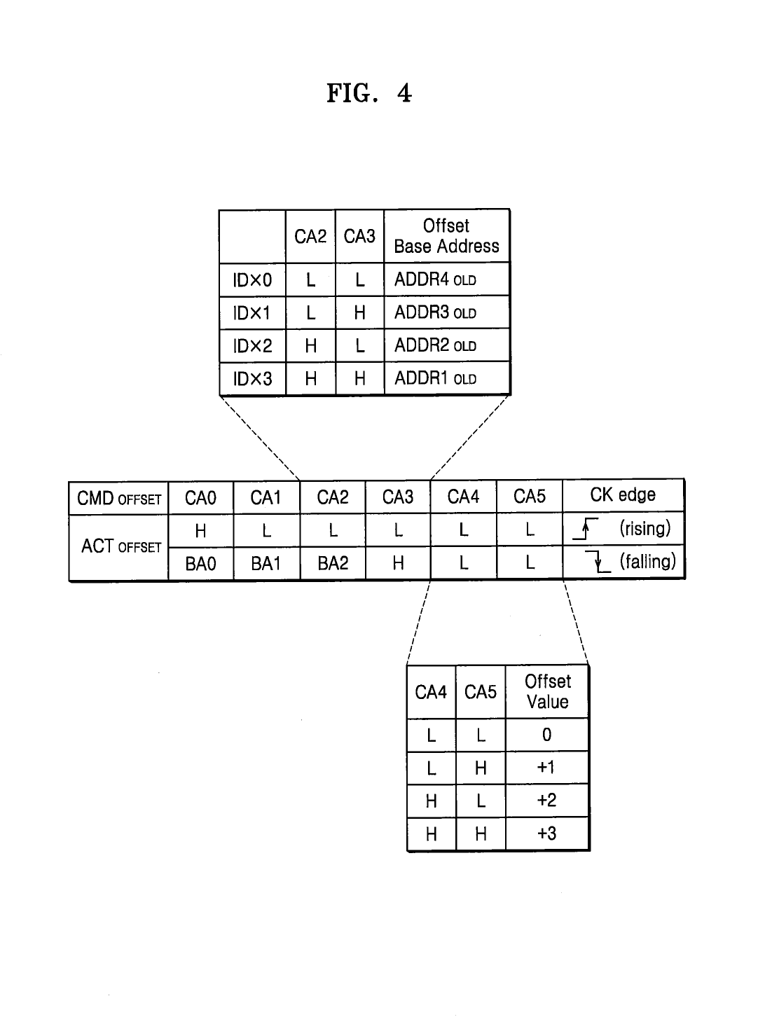

In FIG. 3, the active command ACT uses 2 clock cycles of the clock signal CK. However, the active offset command CMD_{OFFSET} generated according to the offset signal OFFSET of FIG. 2 uses only one clock cycle of the clock signal CK, as illustrated in FIG. 4.

FIG. 4 includes tables illustrating the active offset command CMD_{OFFSET} provided by the command generator 250 of FIG. 2 according to example embodiments of the inventive concept.

Referring to FIG. 4, the active offset command ACT_{OFFSET} may be set with the command/address signals CA[0:5], and uses one clock cycle of the clock signal CK.

The active offset command ACT_{OFFSET} may set a command identification signal indicating the active offset command itself, a signal indicating an offset base address, bank address signals BA0-BA2 indicating bank addresses, and a signal indicating an offset value, with the command/address signals CA[0:5].

The active offset command ACT_{OFFSET} may represent the active offset command itself by setting the command/address signals CA0 and CA1 as logic high (H) and logic low (L), respectively, at a rising edge of the clock cycle of the clock signal CK, and may set command/address signals CA2 and CA3 as a signal indicating an offset base address and the command/address signals CA3 and CA4 as logic low (L) and logic low (L), respectively, at a rising edge of the clock cycle of the clock signal CK.

The offset base addresses set with the command/address signals CA2 and CA3 command/address signal refer to old addresses selected among the old addresses ADDR1_{OLD}-ADDR4_{OLD} stored in the first address storage 230 of FIG. 2.

For example, when the command/address signals CA2 and CA3 are both set to logic low (L), the fourth old address ADDR4_{OLD} with the first index value IDX0 of the first address storage 230 may become an offset base address. When the command/address signals CA2 and CA3 are set as logic low (L) and logic high (H), respectively, the third old address ADDR3_{OLD} with the second index value IDX1 of the first address storage 230 may become the offset base address. When the command/address signals CA2 and CA3 are set to logic high (H) and logic low (L), respectively, the second old address ADDR2_{OLD} with the third index value IDX2 may become the offset base address. When the command/address signals CA2 and CA3 are set to logic high (H) and logic high (H), respectively, the first old address ADDR1_{OLD} with the fourth index value IDX3 may become the offset base address.

The active offset command ACT_{OFFSET} may set the command/address signals CA0, CA1, and CA2 as bank address signals BA0, BA1 and BA2, respectively, at a falling edge of the clock cycle of the clock signal CK, may represent the active offset command itself by setting the command/address signal CA3 as logic high (H), and may set the command/address signals CA4 and CA5 as a signal indicating an offset value.

The active offset command ACT_{OFFSET} may use the command/address signals CA0 and CA1 at a rising edge of the clock cycle of the clock signal CK and the command/address signal CA3 at a falling edge of the clock cycle of the clock signal CK as a command identification signal.

The logic levels of the command/address signals CA4 and CA5 may be represented as 2-bit values. For example, when the command/address signals CA4 and CA5 are both logic low (L), this corresponds to a 2-bit value of 2′b00 and indicates an offset value of 0. When the command/address signals CA4 and CA5 are logic low (L) and logic high (H), respectively, this corresponds to a 2-bit value of 2′b01 and indicates an offset value of +1. When the command/address signals CA4 and CA5 are logic high (H) and logic low (L), this corresponds to a 2-bit value of 2′b10 and indicates an offset value of +2. When the command/address signals CA4 and CA5 are logic high (H) and logic high (H), respectively, this corresponds to a 2-bit value of 2′b11 and indicates an offset value of +3.

For example, assuming that the command/address signals CA2 and CA4 of the active offset command ACT_{OFFSET} are set to logic low (L) and logic low (L), respectively, at a rising edge of the cycle of the clock signal CK, and the command/address signals CA4 and CA5 are set to logic low (L) and logic low (L), respectively, at a falling edge of the cycle of the clock signal CK, the fourth old address ADDR4_{OLD} with the first index value IDX may be the offset base address, and the offset value may be set as 0. Accordingly, an access address to be accessed in response to the active offset command ACT_{OFFSET} may be the fourth old address ADDR4_{OLD}.

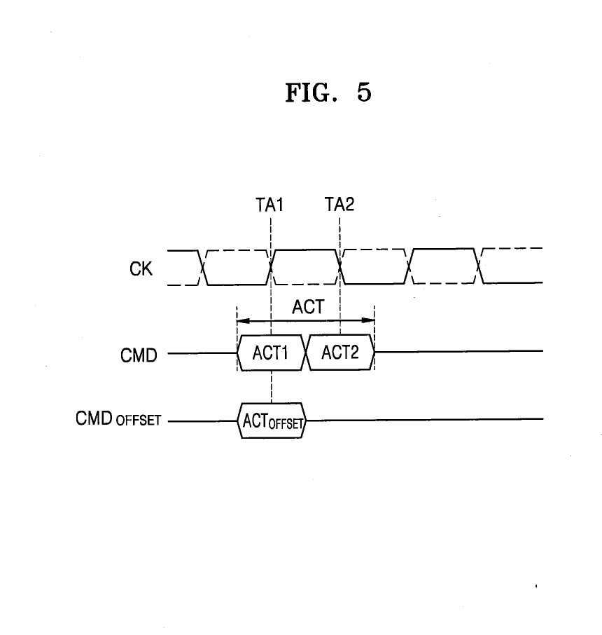

FIG. 5 is a timing diagram of the active command ACT of FIG. 3 and the active offset command ACT_{OFFSET} of FIG. 4 according to example embodiments of the inventive concept.

Referring to FIG. 5, the active command ACT comprises a first active command ACT1 issued at a time TA1 of the clock signal CK and a second active command ACT2 at a time TA2 of the clock signal CK, and uses 2 clock cycles of the clock signal CK. The active offset command ACT_{OFFSET} is issued at a time TA1 of the clock signal CK and uses one clock cycle of the clock signal CK.

The active offset command ACT_{OFFSET} may use one clock cycle of the clock signal CK, one less than the active command CMD uses. Accordingly, when the active offset command ACT_{OFFSET} is received, the memory device 120 of FIG. 2 may reduce the turn-on time of the on-die terminators 270-275 (FIG. 2) and the power consumption.

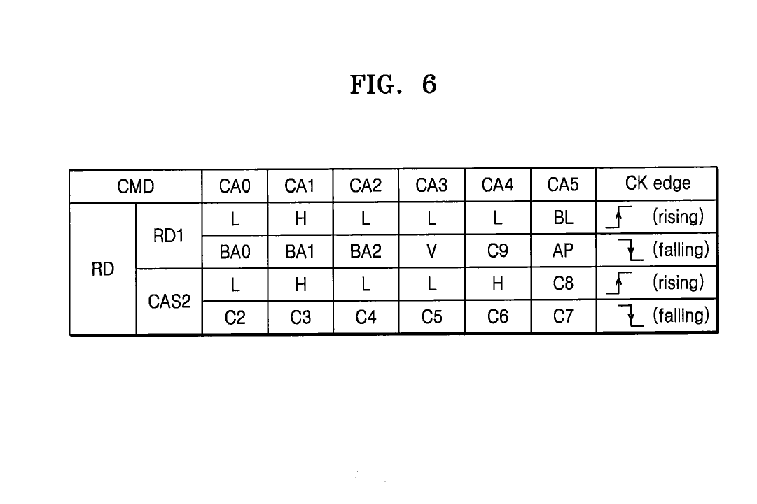

FIG. 6 is a table illustrating a read command RD provided by the command generator 250 of FIG. 2 according to example embodiments of the inventive concept.

Referring to FIG. 6, the read command RD is set with the command/address signals CA[0:5], and comprises a first read command RD1 and a second CAS command CAS2 that use 2 clock cycles of the clock signal CK.

The first read command RD1 may set a command identification signal indicating a read command, a signal indicating a burst length BL, bank address signals BA0-BA2 indicating bank addresses, an address signal C9 indicating some of the column addresses C2-C9, and a signal AP indicating auto-precharge, with the command/address signals CA[0:5].

The first read command RD1 may represent the read command by setting the command/address signals CAO, CA1, CA2, CA3, and CA4 as logic low (L), logic high (H), logic low (L), logic low (L), and logic low (L), respectively, at a rising edge of a first clock cycle of the clock signal CK, and may set the command/address signal CA5 as a signal indicating a burst length BL at a rising edge of a first clock cycle of the clock signal CK. The burst length BL may be set as, for example, BL=2, 4, 8, 16, or 32.

At a falling edge of the first clock cycle of the clock signal CK, the first read command RD1 may set the command/address signals CA0, CA1, and CA2 as bank address signals BA0, BA1, and BA2, respectively, the command/address signal CA4 as a column address signal C9, and the command/address signal CA5 as an auto-precharge signal, and may not use the command/address signal CA3 (as denoted by V).

The second CAS command CAS2 may set a command identification signal indicating a CAS command and address signals C2-C8 indicating the rest of the column addresses C2-C9 with the command/address signals CA[0:5].

At a rising edge of the second clock cycle of the clock signal CK, the second CAS command CAS2 may represent the CAS command by setting the command/address signals CA0, CA1, CA2, CA3, and CA4 as logic low (L), logic high (H), logic low (L), logic low (L), and logic high (H), respectively, and may set the command/address signal CA5 as a column address signal C8.

The second CAS command CAS2 may set the command/address signals CA0, CA1, CA2, CA3, CA4, and CA5 as column address signals C2, C3, C4, C5, C6, and C7, respectively, at a falling edge of the second clock cycle of the clock signal CK.

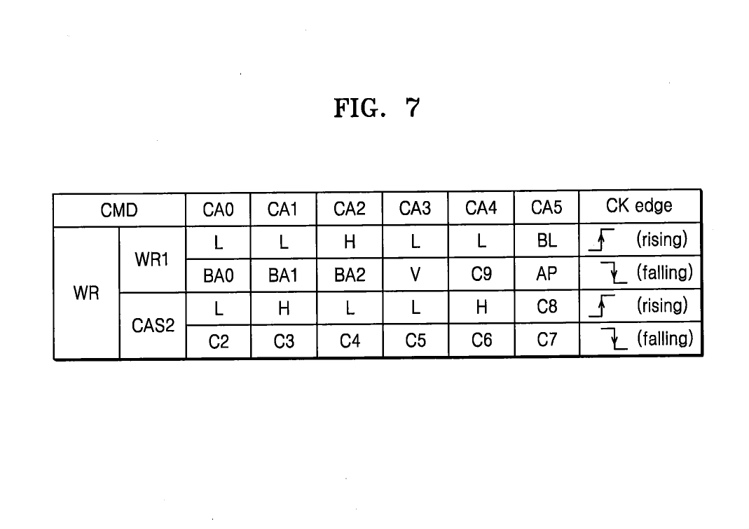

FIG. 7 is a table illustrating a write command WR provided by the command generator 250 of FIG. 2 according to example embodiments of the inventive concept.

Referring to FIG. 7, the write command WR is set with the command/address signals CA[0:5], and comprises a first write command WR1 and a second CAS command CAS2 that use 2 clock cycles of the clock signal CK.

The first write command WR1 may set a command identification signal indicating a write command, a signal indicating a burst length BL, bank address signal BA0-BA2 indicating bank addresses, an address signal C9 indicating some of the column address C2-C9, and a signal AP indicating auto-precharge, with the command/address signals CA[0:5].

The first write command WR1 may represent the write command by setting the command/address signals CA0, CA1, CA2, CA3, and CA4 as logic low (L), logic low (L), logic high (H), logic low (L), and logic low (L), respectively, at a rising edge of the first clock cycle of the clock signal, and may set the command/address signal CA5 as a signal indicating a burst length BL at a rising edge of the first clock cycle of the clock signal. The burst length BL may be set as, for example, BL=2, 4, 8, 16, or 32.

At a falling edge of the first clock cycle of the clock signal CK, the first write command WR1 may set the command/address signals CA0, CA1, and CA2 as bank address signals BA0, BA1, and BA2, respectively, the command/address signal CA4 as a column address signal C9, and the command/address signal CA5 as an auto-precharge signal, and may not use command/address signal CA3 (as denoted by V).

The second CAS command CAS2 may set a command identification signal indicating a CAS command and address signals C2-C8 indicating the rest of the column addresses C2-C9 with the command/address signals CA[0:5].

The second CAS command CAS2 may represent the CAS command by setting the command/address signals CA0, CA1, CA2, CA3, and CA4 as logic low (L), logic high (H), logic low (L), logic low (L), and logic high (H), respectively, at a rising edge of the second clock cycle of the clock signal CK, and may set the command/address signal CA5 as a column address signal C8 at a rising edge of the second clock cycle of the clock signal CK.

The second CAS command CAS2 may set the command/address signals CA0, CA1, CA2, CA3, CA4, and CA5 as column address signals C2, C3, C4, C5, C6, and C7, respectively, at a falling edge of the second clock cycle of the clock signal CK.

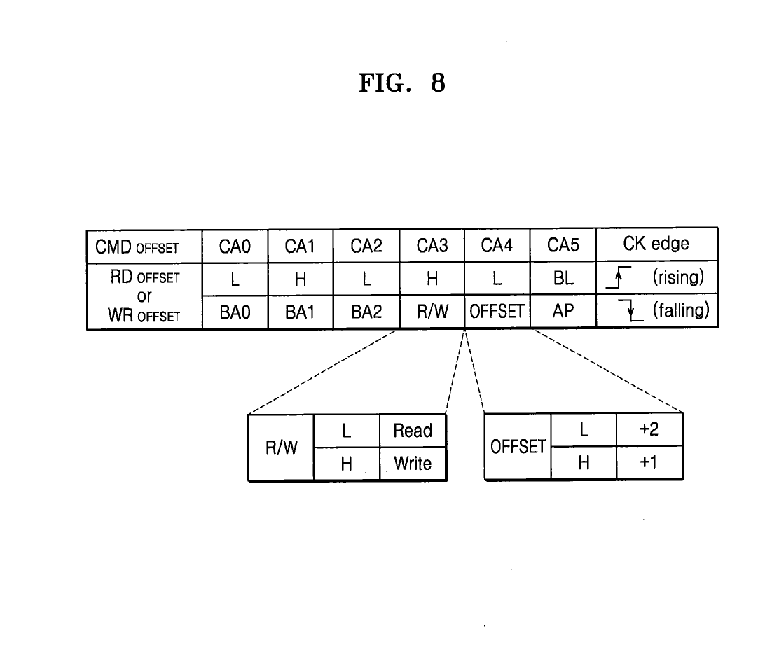

In FIGS. 6 and 7, the read or write command RD or WR uses 2 clock cycles of the clock signal CK. However, the read or write offset command RD_{OFFSET} or WR_{OFFSET} generated according to the offset signal OFFSET of FIG. 2 uses only one clock cycle of the clock signal, as illustrated in FIG. 8.

FIG. 8 includes tables illustrating a read or write offset command RD_{OFFSET} or WR_{OFFSET} provided in the command generator 250 of FIG. 2 according to example embodiments of the inventive concept.

Referring to FIG. 8, the read or write offset command RD_{OFFSET} or WR_{OFFSET} is set with the command/address signals CA[0:5] and uses one clock cycle of the clock signal CK.

The read or write offset command RD_{OFFSET} or WR_{OFFSET} may set a command identification signal indicating a read or write offset command, a signal indicating a burst length BL, bank address signals BA0-BA2 indicating bank addresses, a signal indicating an offset value, and an auto-precharge AP signal with the command/address signals CA[0:5]. The read or write offset command RD_{OFFSET} or WR_{OFFSET} may be a read command or write command having a burst length with auto-precharge function.

The read or write offset command RD_{OFFSET} or WR_{OFFSET} may represent the read or write offset command itself by setting the command/address signals CA0, CA1, CA2, CA3, and CA4 as logic low (L), logic high (H), logic low (L), logic high (H), and logic low (L), respectively, at a rising edge of the cycle of the clock signal CK, and may set the command/address signal CA5 as a signal indicating a burst length BL at a rising edge of the cycle of the clock signal CK. The burst length BL may be set as, for example, BL=2, 4, 8, 16, or 32.

At a falling edge of the cycle of the clock signal, the read or write offset command RD_{OFFSET} or WR_{OFFSET} may set the command/address signals CA0, CA1, and CA2 as bank address signals BA0, BA1, and BA2, the command/address signal CA3 as a read or write offset command, the command/address signal CA4 as a signal indicating an offset value, CA5 command/address signal CA5 as an auto-precharge AP signal.

The read or write offset command RD_{OFFSET} or WR_{OFFSET} may use the command/address signals CA0, CA1, CA2, CA3, and CA4 at a rising edge of the cycle of the clock signal CK and the command/address signal CA3 at a falling edge as a command identification signal. For example, when the command/address signals CA0, CA1, CA2, CA3, and CA4 are set to logic low (L), logic high (H), logic low (L), logic high (H), and logic low (L), respectively, at a rising edge of the cycle of the clock signal CK, it may indicate a read offset command RD_{OFFSET} if the command/address signal CA3 is logic low (L) at a falling edge of the cycle of the clock signal CK, or a write offset command WR_{OFFSET} if the command/address signal CA3 is logic high (H) at a falling edge of the cycle of the clock signal CK.

An offset value represented by the command/address signal CA4 at a falling edge of the cycle of the clock signal CK refers to a difference value between an access column address of a previous read or write offset command and an access column address of the current read or write offset command RD_{OFFSET} or WR_{OFFSET}.

The logic level of the command/address signal CA4 indicating an offset value may be represented as a 1-bit value through a conversion operation. For example, when the command/address signal CA4 is logic low (L), this corresponds to a 1-bit value of 1′b0 and indicates an offset value of +2. When the command/address signal CA4 is logic high (H), this corresponds to a 1-bit value of 1′b1 and indicates an offset value of +1.

For example, assuming that the command/address signal CA4 of the read offset command RD_{OFFSET} is set to logic low (L) at a falling edge of the cycle of the clock signal CK, an access address of the read offset command RD_{OFFSET} may be an offset value of +2 with respect to a previous access column address. When the command/address signal CA4 of the write offset command WR_{OFFSET} is set to logic high (H) at a falling edge of the cycle of the clock signal CK, an access address of the write offset command WR_{OFFSET} may be an offset value of +1 with respect to a previous access column address.

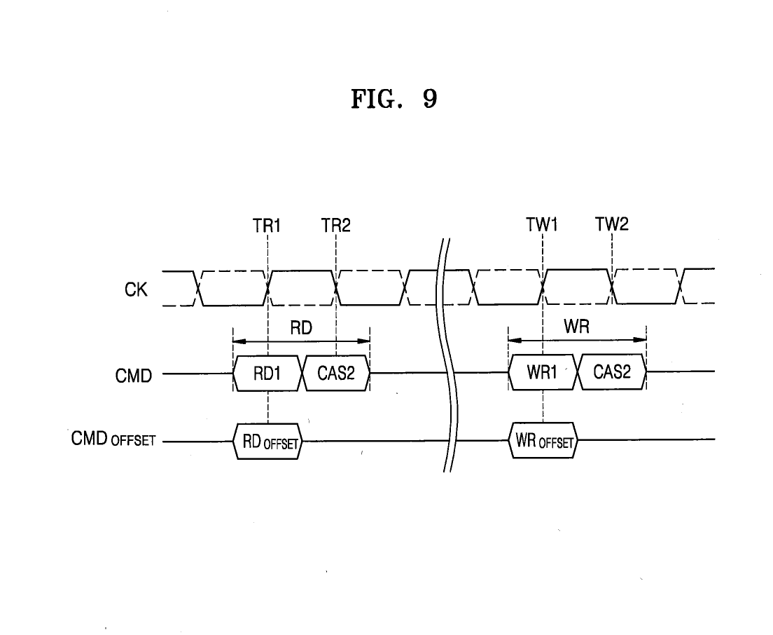

FIG. 9 is a timing diagram of the read command RD1 of FIG. 6 and the read offset command RD_{OFFSET} of FIG. 8, and a timing diagram of the write command WR1 of FIG. 7 and the write offset command WR_{OFFSET} of FIG. 8 according to example embodiments of the inventive concept.

Referring to FIG. 9, the read command RD comprises a first read command RD1 issued at a time TR1 of the clock signal CK and a second CAS command CAS2 issued at a time TR2, and uses 2 clock cycles of the clock signal CK. The read offset command RD_{OFFSET} is issued at a time TR1 of the clock signal CK and uses one clock cycle of the clock signal.

The write command WR comprises a first write command WR1 issued at a time TW1 of the clock signal CK and a second CAS command CAS2 issued at a time TW2, and uses 2 clock cycles of the clock signal CK. The write offset command WR_{OFFSET} is issued at a time TW1 of the clock signal CK and uses one clock cycle of the clock signal CK.

The read offset command RD_{OFFSET} and the write offset command WR_{OFFSET} may each use one clock cycle of the clock signal CK, one less than the read command RD and the write command WR use, respectively. Accordingly, when the read or write offset command RD_{OFFSET} or WR_{OFFSET} is received, the memory device 120 of FIG. 2 may reduce the turn-on time of the on-die terminators 270-275 (FIG. 2) and the power consumption.

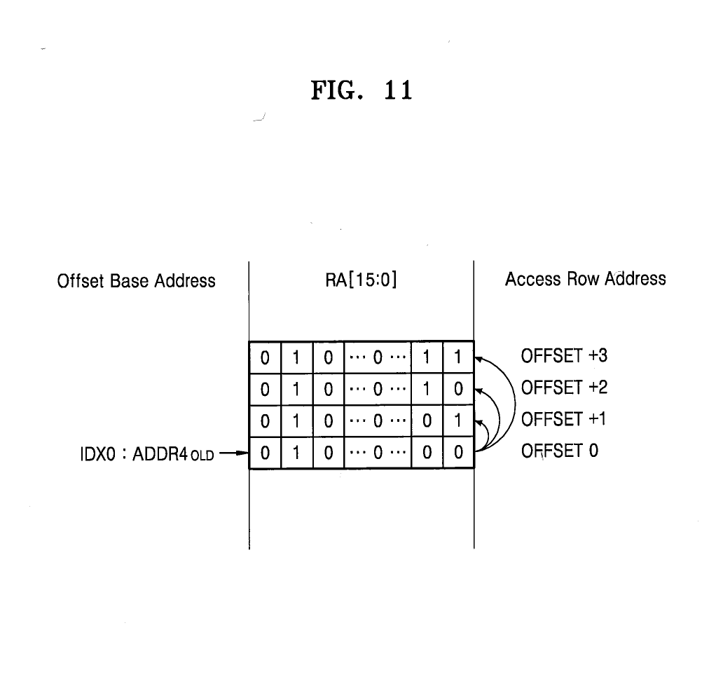

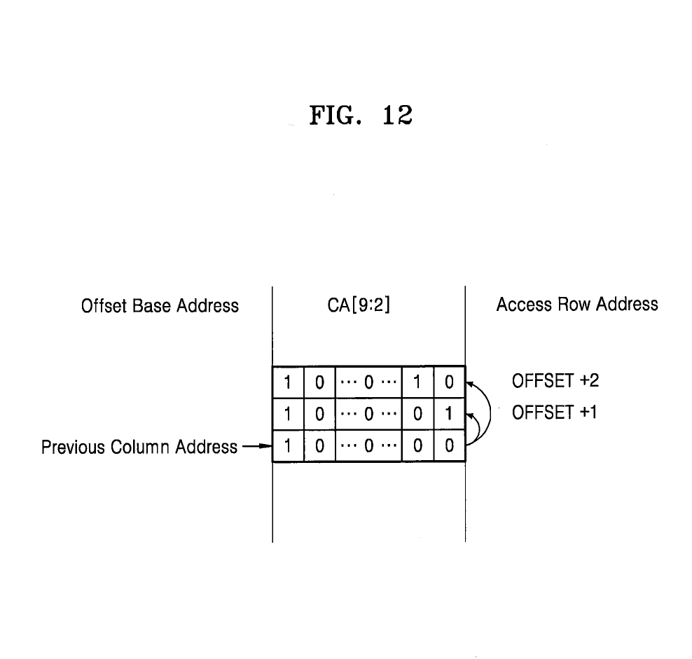

FIG. 10 is a block diagram of the memory device 120 of FIG. 1 according to example embodiments of the inventive concept. The memory device 120 of FIG. 10 will be described in connection with an access row address according to the active offset command of FIG. 11 and an access column address according to the read or write offset command of FIG. 12.

Referring to FIG. 10, the memory device 120 includes a clock (CK) receiver 1010, a command/address (CA) receiver 1020, a control circuit 1030, a second address storage 1040, a bank control logic 1050, a row decoder 106, a column decoder 1070, and a memory cell array 1080.

The clock receiver 1010 receives a clock signal CK transmitted through a clock signal line 11 from the memory controller 110 (FIG. 1) and provides the clock signal CK as an internal clock signal ICK. The command/address receiver 1020 receives a command CMD or an offset command CMD_{OFFSET} transmitted through a command/address bus 12 from the memory controller 110.

The control circuit 1030 generates a control signal CNTL and an internal address signal INT_ADDR according to the command CMD or offset command CMD_{OFFSET} received from the command/address receiver 1020, in response to the internal clock signal ICK. The memory cell array 1080 may include banks 1080A-1080D in which a plurality of memory cells are arranged. The banks 1080A-1080D may be connected to corresponding row decoders 1060A-1060D and column decoders 1070A-1070D, respectively.

The control circuit 1030 may receive an active command ACT of FIG. 3, generate a control signal CNTL corresponding to the active command ACT, and generate an internal address signal INT_ADDR according to the bank address signals bank address signals BA0-BA2 and the row address signals R0-R15. The bank address signals BA0-BA2 provided as the internal address signal INT_ADDR may be provided to the bank control logic 1050, and the row address signals R0-R15 provided as the internal address signal INT_ADDR may be provided to the row decoder 1060.

The bank control logic 1050 may activate row decoders 1060A-1060D that correspond to the bank address signals BA0-BA2, in response to the control signal CNTL. The activated row decoders 1060A-1060D may decode the row address signals R0-R15 in response to the control signal CNTL. The decoded row address signals R0-R15 may be provided to corresponding banks 1080A-1080D and may drive a word line selected from a plurality of word lines connected to the memory cells. Data stored in the memory cells that are connected to the selected word line may be sensed and amplified by a sense amplifier circuit.

The control circuit 1030 may receive a read command RD of FIG. 6, generate a control signal CNTL corresponding to the read command RD, and generate an internal address signal INT_ADDR according to the bank address signals BA0-BA2 and the column address signals C2-C9 .

The control circuit 1030 may receive a write command WR of FIG. 7, generate a control signal CNTL corresponding to the write command WR, and generate an internal address signal INT_ADDR according to the bank address signals BA0-BA2 and the column address signals C2-C9.

The bank address signals BA0-BA2 provided according to the read command RD or write command WR may be provided to the bank control logic 1050, and the column address signals C2-C9 may be provided to the column decoder 1060.

The bank control logic 1050 may activate column decoders 1070A-1070D that correspond to the bank address signals BA0-BA2, in response to the control signal CNTL. The activated column decoders 1070A-1070D may decode the column address signals C2-C9 in response to the control signals CNTL. The decoded column address signals C2-C9 may be provided to corresponding banks 1080A-1080D, and column gating may be performed according to the decoded column addresses C2-C9 to select bit lines that are connected to the memory cells.

The control circuit 1030 may receive an active offset command ACT_{OFFSET} of FIG. 4, generate a control signal CNTL corresponding to the active offset command ACT_{OFFSET}, and generate an internal address signal INT-ADDR according to the bank address signals BA0-BA2. The control signal CNTL corresponding to the active offset command ACT_{OFFSET} may function like a control signal CNTL corresponding to the active command ACT.

The control circuit 1030 may generate an access address of the active offset command ACT_{OFFSET} as the internal address signal INT-ADDR, based on the offset base address and the offset value of the active offset command ACT_{OFFSET}.

The second address storage 1040 may store old addresses provided with the previous commands CMD received by the memory device 120 before the current active offset command ACT_{OFFSET} is received. The second address storage 1040 may store first to fourth old addresses ADDR1_{OLD}-ADDR4_{OLD} identified by the index values IDX0-IDX3, respectively, like the first address storage 230 of the memory controller 110 (FIG. 2).

The index values IDX0-IDX3 of the second address storage 1040 indicate base addresses of the offset signal OFFSET set to the active offset command ACT_{OFFSET}. In an embodiment of FIG. 11, it may be assumed that the fourth old address ADDR4_{OLD} with the first index value IDX0 is an offset base address, and the fourth old address ADDR4_{OLD} has a bit value 16′b0100000000000000 of RA[15:0] row address.

Referring to FIG. 11, when an offset value set to the active offset command ACT_{OFFSET} is 0, the control circuit 1030 may generate an internal address signal INT_ADDR having the same bit value 16′b0100000000000000 of RA[15:0] row address as the fourth old address ADDR4_{OLD}. When an offset value set to the active offset command ACT_{OFFSET} is +1, the control circuit 1030 may add “+1” to the bit value of the fourth old address ADDR4_{OLD} by using an adder 1032 to generate a bit value 16′b0100000000000001 of RA[15:0] row address as the internal address signal INT_ADDR. When an offset value set to the active offset command ACT_{OFFSET} is +2, the control circuit 1030 may add “+2” to the bit value of the fourth old address ADDR4_{OLD} by using the adder 1032 to generate a bit value 16′b0100000000000010 of RA[15:0] row address as the internal address signal INT_ADDR. When an offset value set to the active offset command ACT_{OFFSET} is +3, the control circuit 1030 may add “+3” to the bit value of the fourth old address ADDR4_{OLD} by using the adder 1032 to generate a bit value 16′b0100000000000011 of RA[15:0] row address as the internal address signal INT_ADDR.

The bank address signals and the row address signals of the internal address signal INT_ADDR generated by the control circuit 1030 according to the active offset command ACT_{OFFSET} may be provided to the bank control logic 1050 and the row decoders 1060A-1060D), and, thus, drive a word line selected from the plurality of word lines, the selected word line being connected to a corresponding bank 1080A-1080D.

The control circuit 1030 may receive a read offset command RD_{OFFSET} of FIG. 8, generate a control signal CNTL corresponding to the read offset command RD_{OFFSET}, and generate an internal address signal INT_ADDR according to the active offset command ACT_{OFFSET}). The control signal CNTL corresponding to the read offset command RD_{OFFSET} may function like a control signal CNTL corresponding to the read command RD.

The control circuit 1030 may receive a write offset command WR_{OFFSET} of FIG. 8, generate a control signal CNTL corresponding to the write offset command WR_{OFFSET}, and generate an internal address signal INT_ADDR according to the write offset command WR_{OFFSET}). The control signal CNTL corresponding to the write offset command WR_{OFFSET} may function like the control signal CNTL corresponding to the write command WR.

The control circuit 1030 may generate an access address of the read or write offset command RD_{OFFSET} or WR_{OFFSET} as the internal address signal INT_ADDR, based on the offset value set to the read or write offset command RD_{OFFSET} or WR_{OFFSET}.

In the example embodiment of FIG. 12, it may be assumed that a previous column address accessed by a command issued just before the read or write offset command RD_{OFFSET} or WR_{OFFSET} has a bit value 8′b10000000 of CA[9:2] column address.

Referring to FIG. 12, when an offset value set to the read or write offset command RD_{OFFSET} or WR_{OFFSET} is +1, the control circuit 1030 may generate an internal address signal INT_ADDR having a bit value 8′b10000001 of CA[9:2] column address by adding “+1” to a bit value 8′b10000000 of the previous column address. When an offset value set to the read or write offset command RD_{OFFSET} or WR_{OFFSET} is +2, the control circuit 1030 may generate an internal address signal INT_ADDR having a bit 8′b10000010 value of CA[9:2] column address by adding “+2” to a bit value 8′b10000000 of the previous column address.

The bank address signals and the row address signals of the internal address signal INT_ADDR generated by the control circuit 1030 according to the read or write offset command RD_{OFFSET} or WR_{OFFSET} may be provided to the bank control logic 1050 and the column decoders 1070A-1070D and column gating may be performed on a corresponding bank 1080A-1080D to select bit lines that are connected to the memory cells.

As described above, the memory device 120 may receive an offset command CMD_{OFFSET} that does not include an access address signal for one cycle of a clock signal CK with command/address signals CA. The memory device 120 may generate an access address signal of the offset command CMD_{OFFSET} based on an offset value(s) set to a portion of the command/address signals CA of the offset command CMD_{OFFSET}. The memory device 120 may generate a row address of the access address signal according to an active offset command ACT_{OFFSET} and a column address of the access address signal according to a read Or write offset command RD_{OFFSET} or WR_{OFFSET}.

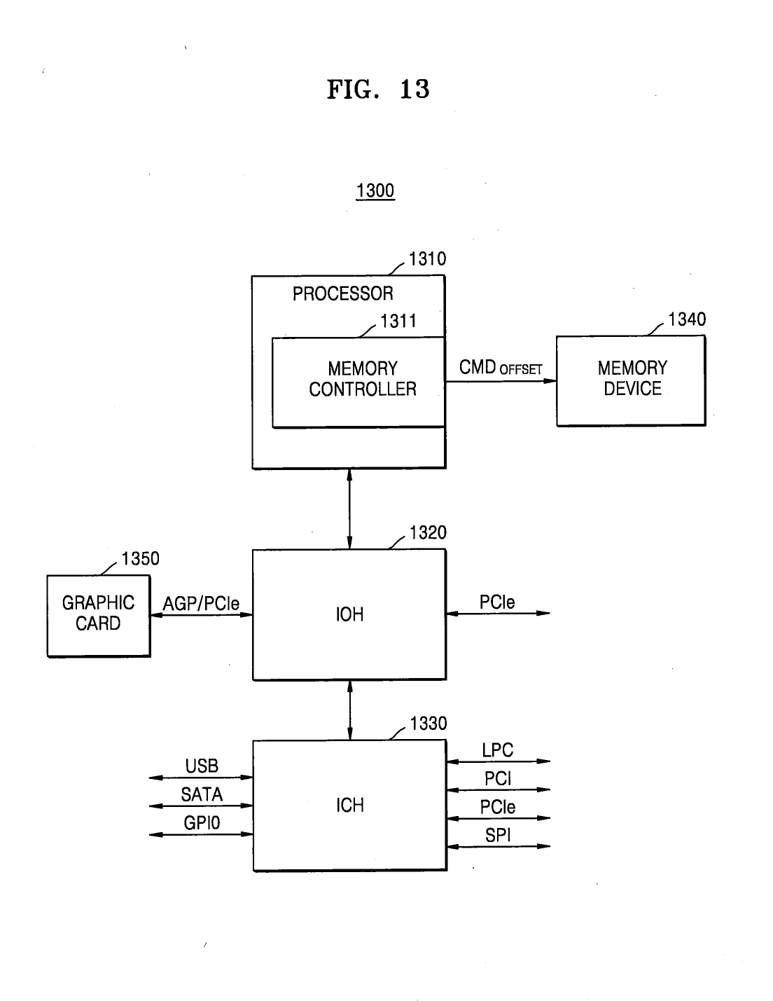

FIG. 13 is a block diagram illustrating an example of a computer system 1300 that includes a memory system supporting an offset command according to example embodiments of the inventive concept.

Referring to FIG. 13, the computer system 1300 includes a processor 1310, an input/output hub 1320, an input/output controller hub 1330, a memory device 1340, and a graphic card 1350. According to some embodiments, the computer system 1300 may be an arbitrary computing system, such as a personal computer (PC), a server computer, a workstation, a laptop computer, a mobile phone, a smart phone, a personal digital assistant (PDA), a portable multimedia player (PMP), a digital camera, a digital television (TV), a set-top box, a music player, a portable game console, and a navigation system.

The processor 1310 may perform various computing functions, such as particular calculations or tasks. For example, the processor 1310 may be a microprocessor or a central processing unit (CPU). In some embodiments, the processor 1310 may include a single processor core or a plurality of processor cores. For example, the processor 1310 may include dual cores, quad cores, hexa cores, or the like. Furthermore, although FIG. 13 shows the computer system 1300 including a single processor 1310, the computer system 1300 may include a plurality of processors according to some embodiments. Furthermore, the processor 1310 may further include a cache memory that is arranged inside or outside the processor 1310.

The processor 1310 may include a memory controller 1311 that controls operations of the memory device 1340. The memory controller 1311 included in the processor 1310 may be referred to as an integrated memory controller (IMC). In some embodiments, the memory controller 1311 may be arranged inside the input/output hub 1320. The input/output hub 1320 including the memory controller 1311 may be referred to as a memory controller hub (MCH). In some other embodiments, the memory controller 1311 may be implemented as a separate device from the processor 1310 or the input/output hub 1320.

The memory controller 1311 and the memory device 1340 may constitute a memory system. The memory controller 1311 may transmit an offset command CMD_{OFFSET} to the memory device 1340 for one clock cycle of a clock signal CK transmitted to the memory device 1340, the offset command CMD_{OFFSET} not including an access address signal, but including an offset signal implying the access address signal. The memory device 1340 may receive the offset command CMD_{OFFSET} that does not include an address access signal for one clock cycle of the clock signal CK through the command/address signals CA. The memory device 1340 may generate an access address signal of the offset command CMD_{OFFSET} based on an offset signal set to the offset command CMD_{OFFSET}. The memory device 1340 may generate a row address of the access address signal according to an active offset command, and a column address of the access address signal according to a read or write offset command.

The input/output hub 1320 may manage data transmissions between devices like the graphic card 1350 and the processor 1310. The input/output hub 1320 may be connected to the processor 1310 via various types of interfaces. For example, the input/output hub 1320 and the processor 1310 may be connected to each other via various types of standard interfaces, including front side bus (FSB), system bus, HyperTransport, Lighting data transport (LDT), QuickPath interconnect (QPI), common system interface (CSI), peripheral component interface-express (PCIe), and the like. Although FIG. 13 shows the computer system 1300 including the single input/output hub 1320, the computer system 1300 may include a plurality of input/output hubs according to some embodiments.

The input/output hub 1320 may provide various interfaces to devices. For example, the input/output hub 1320 may provide an accelerated graphics port (AGP) interface, a peripheral component interface-express (PCIe) interface, a communications streaming architecture (CSA) interface, etc.

The graphic card 1350 may be connected to the input/output hub 1320 via an AGP or a PCIe. The graphic card 1350 may control a display apparatus (not shown) for displaying images. The graphic card 1350 may include an internal processor for processing image data and an internal semiconductor memory device. In some embodiments, the input/output hub 1320 may include a graphic device with the graphic card 1350 arranged outside the input/output hub 1320 or may include a graphic device arranged inside the input/output hub 1320 instead of the graphic card 1350. A graphic device included in the input/output hub 1320 may be referred to as an integrated graphic device. Furthermore, the input/output hub 1320 including a memory controller and a graphic device may be referred to as a graphics and memory controller hub (GMCH).

The input/output controller hub 1330 may perform data buffering and interface arbitration for efficient operations of various system interfaces. The input/output controller hub 1330 may be connected to the input/output hub 1320 via an internal bus. For example, the input/output hub 1320 and the input/output controller hub 1330 may be connected to each other via direct media interface (DMI), hub interface, enterprise Southbridge interface (ESI), PCIe, etc.

The input/output controller hub 1330 may include various interfaces for peripheral devices. For example, the input/output controller hub 1330 may include a universal serial bus (USB) port, a serial advanced technology attachment (SATA), a general purpose input/output (GPIO), a low pin count (LPC) bus, a serial peripheral interface (SPI), a PCI, a PCIe, etc.

In some embodiments, two or more of the processor 1310, the input/output hub 1320, and the input/output controller hub 1330 may be embodied as a single chipset.

While the inventive concept has been particularly shown and described with reference to embodiments thereof, it will be understood that various changes in form and details may be made therein without departing from the scope of the following claims.

what is claimed is:

1. A memory device, comprising:
a clock receiver configured to receive a clock signal from a controller; and
a control circuit configured to receive an offset command signal from the controller in synchronization with the clock signal, the offset command signal not comprising an access address signal, and to generate an access address signal based on the offset command signal.

2. The memory device of claim 1, wherein the memory device is configured to receive the offset command signal for one cycle of the clock signal.

3. The memory device of claim 1, wherein the memory device is configured to receive a difference value between an address signal received prior to the offset command signal and the access address signal generated by the control circuit, as the offset command signal.

4. The memory device of claim 3, wherein the memory device further comprises an address storage configured to store a plurality of previous address signals, each of the plurality of previous address signals being identified by an index value, and
wherein the offset command signal comprises the index value, and the previous address signals of the address storage corresponding to the index value of the offset command signal is set as an offset base address.

5. The memory device of claim 4, wherein the offset command signal is an active offset command signal, and the active offset command signal comprises a command identification signal indicating the active offset command signal, the offset base address, and an offset signal, which is assigned to a portion of command/address signals.

6. The memory device of claim 5, wherein the control circuit is configured to generate a row address of the access address signal based on the active offset command signal.

7. The memory device of claim 3, wherein the offset command signal is a read or write offset command signal, and the read or write offset command signal comprises a command identification signal indicating the read or write offset command signal, and an offset signal, which is assigned to a portion of command/address signals.

8. The memory device of claim 7, wherein the control circuit is configured to generate a column address of the access address signal based on the read or write offset command signal.

9. The memory device of claim 1, wherein the memory device further comprises an on-die terminator connected to signal lines, which are configured to carry command/address signals representing the offset command signal.

10. A memory controller, comprising:
a clock transmitter configured to transmit a clock signal to a memory device; and
a command generator configured to transmit an offset command signal in synchronization with the clock signal, the offset command signal not comprising an access address signal, but comprising an offset signal that comprises access address offset information.

11. The memory controller of claim 10, wherein the memory controller is configured to transmit the offset command signal for one cycle of the clock signal.

12. The memory controller of claim 10, wherein the memory controller further comprises an address offset calculator configured to output a difference value between a previous address signal associated with a command signal transmitted prior to the offset command signal and the access address signal as the offset signal.

13. The memory controller of claim 12, wherein the memory controller further comprises an address storage configured to store a plurality of previous address signals, each of the plurality of previous address signals being identified by an index value, and wherein the offset command signal comprises the index value, and the previous address signals of the address storage corresponding to the index value of the offset command signal is set as an offset base address.

14. The memory controller of claim 13, wherein the offset command signal is an active offset command signal, and the active offset command signal comprises a command identification signal indicating the active offset command signal, the offset base address, and the offset signal, which is assigned to a portion of command/address signals,
the active offset command signal being associated with a row address of the memory device.

15. The memory controller of claim 13, wherein the offset command signal is a read or write offset command signal, and the read or write offset command signal comprises a command identification signal indicating the read or write offset command signal, and the offset signal, which is assigned to a portion of command/address signals, and
the read or write offset command signal being associated with a column address of the memory device.

16. A memory device, comprising:
a clock receiver configured to receive a clock signal from a memory controller; and
a control circuit that is configured to receive a first command signal comprising first access address signals in synchronization with n cycles of the clock signal and is configured to receive a second offset command signal comprising an offset signal based on the first access address signals in synchronization with m cycles of the clock signal;
wherein the control circuit is further configured to generate second access address signals based on the offset signal; and
wherein m is less than n.

17. The memory device of claim 16, wherein the offset signal comprises a difference value between the second access address signal and the first access address signal.

18. The memory device of claim 16, wherein the offset command signal is an active offset command signal comprising command/access signals and the offset signal is assigned to a portion of the command/access signals.

19. The memory device of claim 16, wherein the offset command signal is a read or write offset command signal comprising command/access signals and the offset signal is assigned to a portion of the command/access signals.

20. The memory device of claim 16, wherein m=n/2.
